(19) United States
(12) Patent Application Publication
(10) Pub. No.: US 2010/0193778 A1
(43) Pub. Date: Aug. 5, 2010

(54) ORGANIC LIGHT EMITTING DIODE DISPLAY AND METHOD OF MANUFACTURING THE SAME

(75) Inventors: Chi-Wook An, Yongin-City (KR); Ji-Yeon Baek, Yongin-City (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-City (KR)

(21) Appl. No.: 12/697,428

(22) Filed: Feb. 1, 2010

(30) Foreign Application Priority Data
Feb. 2, 2009 (KR) 10-2009-0008022

(51) Int. Cl. H01L 51/52; H01L 33/00; H01L 51/56

(52) U.S. Cl. 257/40; 257/88; 257/59; 438/34; 257/E51.022; 257/E33.005; 257/E33.013; 257/E33.053; 438/29

(57) ABSTRACT

An organic light emitting diode display with first and second substrates, and a method of manufacturing the organic light emitting diode display. The first substrate has a plurality of first organic light emitting diodes each having a first emissive area and a first non-emissive area, and a first driving circuit unit for driving the first organic light emitting diodes. The second substrate has a plurality of second organic light emitting diodes each having a second emissive area and a second non-emissive area, and a second driving circuit unit for driving the second organic light emitting diodes. The first emissive areas of the first organic light emitting diodes face the second non-emissive areas of the second organic light emitting diodes, respectively, and the second emissive areas of the second organic light emitting diodes face the first nonemissive area of the first organic light emitting diodes, respectively.

### CROSS-REFERENCE TO RELATED APPLICATION

This application claims the benefit of Korean Application No. 10-2009-0008022 filed Feb. 2, 2009, in the Korean Intellectual Property Office, the disclosure of which is incorporated herein by reference.

### BACKGROUND OF THE INVENTION

1. Field of the Invention

Aspects of the present invention relate to an organic light emitting diode display and a method of manufacturing the same, and more particularly, to an organic light emitting diode display with effectively heightened resolution and a manufacturing method thereof.

2. Description of the Related Art

An organic light emitting diode (OLED) display has an emissive characteristic, and differs from a liquid crystal display (LCD) in that it does not require a separate light source and thereby has comparatively reduced thickness and weight. Furthermore, as the organic light emitting diode display has characteristics such as low power consumption, high luminance, and a short response time, it has been spotlighted as a next generation display device for portable electronic appliances.

The OLED displays images by using a plurality of pixels. A pixel is a minimal image display unit. An organic light emitting diode is formed at each pixel. That is, with the organic light emitting diode display, the image is displayed with light emitted from organic light emitting diodes respectively formed at the pixels. The organic light emitting diode includes a hole injection electrode, an organic emissive layer, and an electron injection electrode.

The OLED has an emissive area and a non-emissive area, and the emissive area of the organic light emitting diode is spaced apart from that of the neighboring organic light emitting diodes by interposing the non-emissive area therebetween. In this structure, the emissive areas are spaced apart from each other by interposing the corresponding non-emissive areas in order to satisfy the processing conditions and prevent possible device failures.

Accordingly, as the resolution of the organic light emitting diode display is heightened, that is, as the number of pixels per unit area increases, the emissive area is reduced. Such a reduction in emissive area deteriorates the organic emissive layer, and has a negative effect on the lifespan of the organic light emitting diode display.

### SUMMARY OF THE INVENTION

Aspects of the present invention have been made in an effort to provide an organic light emitting diode display having advantages of effectively heightening the resolution and simultaneously preventing the occurrence of device failures, and a manufacturing method thereof.

An exemplary embodiment of the present invention provides an organic light emitting diode display with first and second substrates. The first substrate has a plurality of first organic light emitting diodes each having a first emissive area and a first non-emissive area, and a first driving circuit unit for driving the first organic light emitting diodes. The second substrate has a plurality of second organic light emitting diodes each having a second emissive area and a second non-emissive area, and a second driving circuit unit for driving the second organic light emitting diodes. The first emissive areas of the first organic light emitting diodes face the second non-emissive areas of the second organic light emitting diodes, respectively, and the second emissive areas of the second organic light emitting diodes face the first non-emissive areas of the first organic light emitting diodes, respectively.

The first and second organic light emitting diodes may emit light in the same direction.

The first emissive areas of each of the first organic light emitting diodes and the second emissive areas of each of the second organic light emitting diodes may be alternately arranged on respective opposing substrates, so as to not overlap in a direction parallel to the first and second substrates.

Each of the first organic light emitting diodes may include a first pixel electrode, a first common electrode, and a first organic emissive layer disposed between the first pixel electrode and the first common electrode, and each of the second organic light emitting diodes may include a second pixel electrode, a second common electrode, and a second organic emissive layer disposed between the second pixel electrode and the second common electrode.

The first and second organic emissive layers may be formed by depositing an organic material using a metal mask, an ink-jet method, or a laser induced thermal imaging (LITI) method.

The first substrate may further include a first pixel definition layer for defining the first emissive area through a first opening, and the second substrate may further include a second pixel definition layer for defining the second emissive area through a second opening, while the first and second organic emissive layers emit light within the first and second openings, respectively.

The light generated from the first organic emissive layer may be emitted to pass through the second pixel definition layer.

The distance between neighboring first emissive areas and the distance between neighboring second emissive areas may each be at least 15 microns (μm).

The first and second pixel definition layers may be formed of an organic material.

The first driving circuit unit may further include a first driving thin film transistor connected to the first pixel electrodes of the first organic light emitting diodes, and the second driving circuit unit may further include a second driving thin film transistor connected to the second pixel electrodes of the second organic light emitting diodes.

Another exemplary embodiment of the present invention provides a method of manufacturing an organic light emitting diode display. With the method, a first substrate is formed such that it has a plurality of first organic light emitting diodes each having a first emissive area and a first non-emissive area, and a first driving circuit unit for driving the first organic light emitting diodes. A second substrate is formed such that it has a plurality of second organic light emitting diodes each having a second emissive area and a second non-emissive area, and a second driving circuit unit for driving the second organic light emitting diodes. The first and second substrates are then arranged such that the first emissive areas of the first organic light emitting diodes faces the second non-emissive areas of the second organic light emitting diodes, respectively, and the second emissive areas of the second organic light emitting diodes faces the first non-emissive areas of the first organic light emitting diodes. Thereafter, the first and second substrates are attached to each other so as to seal the substrates in a vacuum-tight manner.

The plurality of first and second organic light emitting diodes may emit light in the same direction.

The first and second substrates may be arranged such that the first emissive areas of each of the first organic light emitting diodes and the second emissive areas of each of the second organic light emitting diodes are alternately disposed on respective opposing substrates, so as to not overlap in a direction parallel to the first and second substrates.

With the method of manufacturing an organic light emitting diode display, the first organic light emitting diodes may each include a first pixel electrode, a first common electrode, and a first organic emissive layer disposed between the first pixel electrode and the first common electrode, and the second organic light emitting diodes may each include a second pixel electrode, a second common electrode, and a second organic emissive layer disposed between the second pixel electrode and the second common electrode.

The first and second organic emissive layers may be formed by depositing an organic material using a metal mask, an ink-jet method, or a laser induced thermal imaging (LITI) method.

The first substrate may further include a first pixel definition layer for defining the first emissive area with a first opening, and the second substrate may further include a second pixel definition layer for defining the second emissive area with a second opening, while the first and second organic emissive layers emit light within the first and second openings, respectively.

The light generated from the first organic emissive layer may be emitted to the outside while passing through the second pixel definition layer.

The distance between neighboring first emissive areas and the distance between neighboring second emissive areas may be at least 15 microns (μm).

The first and second pixel definition layers may be formed of an organic material.

The first driving circuit unit may further include a first driving thin film transistor connected to the first pixel electrodes of the first organic light emitting diodes, and the second driving circuit unit may further include a second driving thin film transistor connected to the second pixel electrodes of the second organic light emitting diodes.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of an organic light emitting diode (OLED) display with first and second substrates according to an exemplary embodiment of the present invention.

FIG. 2 is a layout view illustrating the inner structure of the first substrate shown in FIG. 1.

FIG. 3 is a layout view illustrating the inner structure of the second substrate shown in FIG. 1. FIG. 4 is a partial sectional view of the organic light emitting diode display taken along the IV-IV line of FIG. 2.

FIG. 5 is a partial plan view illustrating the arrangement of first and second organic light emitting diodes shown in FIG. 1.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain aspects of the present invention by referring to the figures.

Structural parts that are irrelevant to the description are omitted in order to clearly describe aspects of the present invention, and like reference numerals designate like elements throughout the specification.

Furthermore, as the size and thickness of the respective structural components shown in the drawings are arbitrarily illustrated for explanatory convenience, aspects of the present invention are not necessarily limited to as illustrated.

In the drawings, the thickness of layers, films, panels, regions, etc., are exaggerated for clarity, better understanding, and convenience in description. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Furthermore, even though an active matrix (AM) organic light emitting diode (OLED) display having a 2Tr-1 Cap structure with two thin film transistors (TFT) and one capacitor at each pixel is illustrated in the appended drawings, aspects of the present invention are not limited thereto. The organic light emitting diode display may have three or more thin film transistors and two or more capacitors at each pixel, and various structures with separate wires. A pixel is a minimal image display unit, and the organic light emitting diode display makes the image display by way of a plurality of pixels.

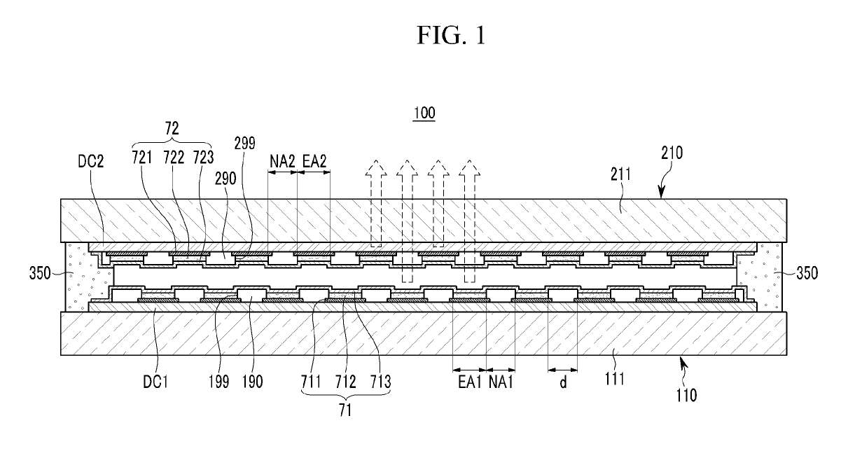

An exemplary embodiment of the present invention will now be described with reference to FIG. 1.

As shown in FIG. 1, an organic light emitting diode display 100 according to an exemplary embodiment of the present invention includes a first substrate 110, a second substrate 210, and a sealant 350.

The first substrate 110 includes a first substrate member 111, and a first organic light emitting diode 71 and a first driving circuit unit DC1 formed on the first substrate member 111.

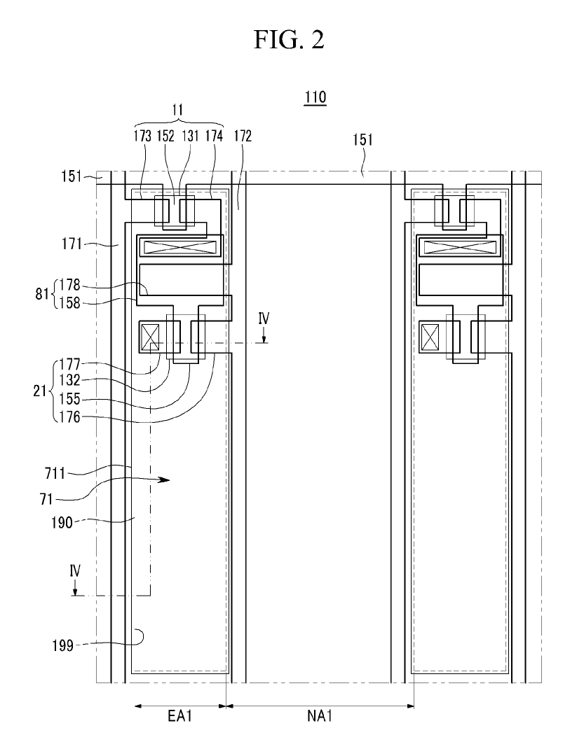

As shown in FIG. 2, the first driving circuit unit DC1 has two or more thin film transistors (TFT) 11 and 21 and one or more capacitors 81 at each pixel. The first driving circuit unit DC1 is electrically connected to the first organic light emitting diode 71 to drive it.

The first organic light emitting diode 71 includes a first pixel electrode 711, a first organic emissive layer 712, and a first common electrode 713. The first organic emissive layer 712 is disposed between the first pixel electrode 711 and the first common electrode 713, and emits light when voltages are applied to the first pixel electrode 711 and the first common electrode 713 in accordance with the driving signals from the first driving circuit unit DC1. The light generated from the first organic emissive layer 712 is emitted in the direction of the second substrate 210.

Furthermore, the first organic light emitting diode 71 is demarcated into a first emissive area EA1 and a first non-emissive area NA1. The first organic emissive layer 712 emits light at the first emissive area EA1 thereof.

As is illustrated in FIG. 1, the first driving circuit unit DC1 is formed on the first substrate member 111 while the first organic light emitting diode 71 is formed on the first driving circuit unit DC1, but an exemplary embodiment of the present invention is not limited thereto. The structure and disposition of the first driving circuit unit DC1 and the first organic light emitting diode 71 may be variously altered as is well known to those skilled in the art.

The second substrate 210 includes a second substrate member 211, and a second organic light emitting diode 72 and a second driving circuit unit DC2 formed on the second substrate member 211.

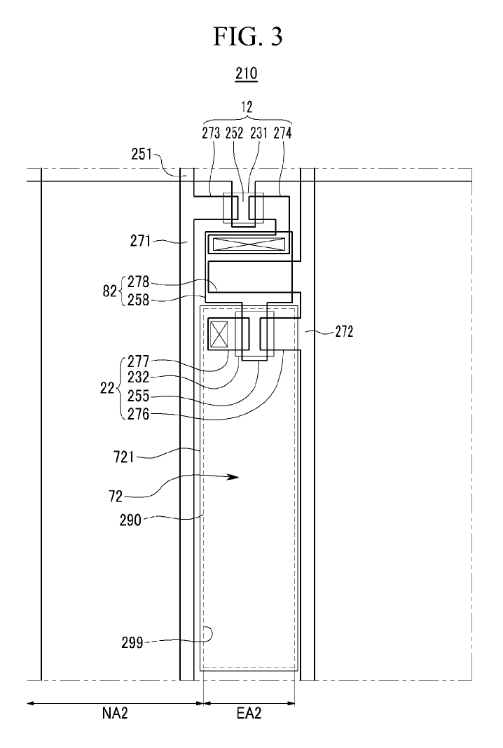

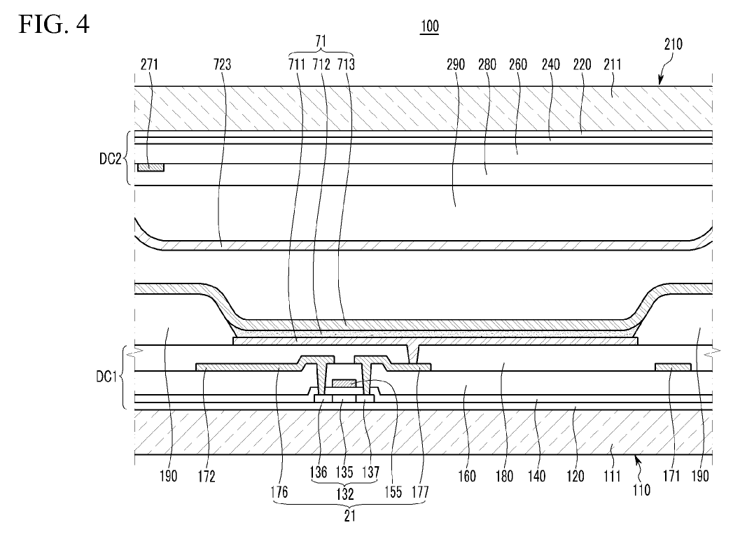

As shown in FIG. 3, the second driving circuit unit DC2 has two or more thin film transistors (TFT) 12 and 22 and one or more capacitors 82, similar to the first driving circuit unit DC1. The second driving circuit unit DC2 is electrically connected to the second organic light emitting diode 72 to drive it.

The second organic light emitting diode 72 includes a second pixel electrode 721, a second organic emissive layer 722, and a second common electrode 723. The second organic emissive layer 722 is disposed between the second pixel electrode 721 and the second common electrode 723, and emits light when voltages are applied to the second pixel electrode 721 and the second common electrode 723 in accordance with the driving signals from the second driving circuit unit DC2. The light generated from the second organic emissive layer 722 is emitted in a direction away from the first substrate 110. Accordingly, the first and second organic light emitting diodes 71 and 72 are formed such that they emit light in the same direction. Consequently, the light components emitted from the first and second organic light emitting diodes 71 and 72 are merged to thereby display an image.

The second organic light emitting diode 72 is demarcated into a second emissive area EA2 and a second non-emissive area NA2. The second organic emissive layer 722 emits light at the second emissive area EA2 thereof.

As is illustrated in FIG. 1, the second driving circuit unit DC2 is formed under the second substrate member 211 while the second organic light emitting diode 72 is formed under the second driving circuit unit DC2, but an exemplary embodiment of the present invention is not limited thereto. The structure and disposition of the second driving circuit unit DC2 and the second organic light emitting diode 72 may be variously altered as is well known to those skilled in the art.

Particularly, as illustrated in FIG. 1, the first and second organic light emitting diodes 71 and 72 are similar to each other in structure, however an exemplary embodiment of the present invention is not limited thereto. The first and second organic light emitting diodes 71 and 72 should be formed at different places, but they emit light in the same direction so as to display an image. The first and second organic light emitting diodes 71 and 72 may be altered in structure within the available range as is well known to those skilled in the art. Furthermore, the first and second driving circuit units DC1 and DC2, respectively connected to the first and second organic light emitting diodes 71 and 72, may be different in structure from each other.

Although not shown in the drawings, the organic light emitting diode display 100 may further include a driving circuit board connected to the first and second driving circuit units DC1 and DC2 to supply driving signals and power thereto. The driving circuit board may be electrically connected to the edge of the first substrate 110 or the second substrate 210. For example, if the driving circuit board is connected to the edge of the first substrate 110, the first driving circuit unit DC1 may be connected with the driving circuit board via a wire on the first substrate 110. The second driving circuit unit DC2 may be connected with the driving circuit board via the first substrate 110 by way of an electrical connector (not shown). The electrical connector (not shown) may be formed at the edges of the first and second substrates 110 and 210 within the sealant 350 or separately from the sealant 350.

Meanwhile, the first and second substrates 110 and 210 are arranged such that the first emissive area EA1 of the first organic light emitting diode 71 faces the second non-emissive area NA2 of the second organic light emitting diode 72, while the second emissive area EA2 of the second organic light emitting diode 72 faces the first non-emissive area NA1 of the first organic light emitting diode 71.

Furthermore, the first emissive areas EA1 of the first organic light emitting diodes 71 and the second emissive areas EA2 of the second organic light emitting diodes 72 are alternately disposed in a direction parallel to the first and second substrates 110 and 210.

The first substrate 110 further includes a first pixel definition layer 190, and the second substrate 210 further includes a second pixel definition layer 290. The first pixel definition layer 190 defines the first emissive area EA1 with a first opening 199. The second pixel definition layer 290 defines the second emissive area EA2 with a second opening 299. That is, the first and second organic emissive layers 712 and 722 emit light within the first opening 199 of the first pixel definition layer 190 and the second opening 299 of the second pixel definition layer 290, respectively.

The first opening 199 of the first pixel definition layer 190 faces the second pixel definition layer 290, and the second opening 299 of the second pixel definition layer 290 faces the first pixel definition layer 190. The light generated from the first organic emissive layer 712 is emitted to the outside while passing through the second pixel definition layer 290.

The distance d between the neighboring first emissive areas EA1, that is, the length of the first non-emissive area NA1 disposed between two neighboring first emissive areas EA1, is preferably established to be 15 microns (μm) or more. If the distance d between the first emissive area neighbors EA1 is less than 15 microns (μm), the first organic emissive layer 712 intrudes into the neighboring organic emissive layer 712 during the processing so that they may be needlessly mixed with each other. Furthermore, it is necessary in forming the first openings 199 at the first pixel definition layer 190 through a photolithography process that the distance between the first opening neighbors 199 should be established to be minimally 15 microns or more. Similarly, the distance between the second emissive area neighbors EA2, that is, the length of the second non-emissive area NA2 disposed between the second emissive area neighbors EA2, is preferably established to be 15 microns or more.

The first emissive areas EA1 of the first organic light emitting diodes 71 and the second emissive areas EA2 of the second organic light emitting diodes 72 are alternately arranged on opposing substrates in a direction parallel to the first and second substrates 110 and 210.

The sealant 350 is disposed along the edges of the first and second substrates 110 and 210 so as to attach the first and second substrates 110 and 210 to each other and seal them in a vacuum-tight manner.

With the above-structured organic light emitting diode display 100, the resolution can be enhanced effectively while preventing possible device failures.

That is, with the organic light emitting diode display 100, the first and second organic light emitting diodes 71 and 72 separately formed on the first and second substrates 110 and 210 facing each other emit light in the same direction to thereby display an image. Consequently, it is possible with the organic light emitting diode display 100 to solve such a problem that as the resolution is increased, the emissive area is reduced due to the non-emissive area, and the luminous efficiency is deteriorated. Furthermore, the organic light emitting diode display 100 is prevented from being reduced in lifespan.

Meanwhile, as the improvement in luminous efficiency is not based on a reduction in the non-emissive area, the possible processing failures induced by the reduction of the non-emissive area can be prevented.

The internal structure of an organic light emitting diode display 100 according to an exemplary embodiment of the present invention will now be described in detail with reference to FIG. 2 through FIG. 4. FIG. 2 is a layout view illustrating a pixel structure centered on the first substrate 110, and FIG. 3 is a layout view illustrating a pixel structure centered on the second substrate 210. FIG. 4 is a cross-sectional view of the first and second substrates 110 and 210 taken along the III-III line of FIG. 2.

The first substrate 110 includes a first switching thin film transistor 11, a first driving thin film transistor 21, a first capacitor 81, and a first organic light emitting diode (OLED) 71, which are formed at each pixel. The first substrate 110 further includes first gate lines 151 arranged in a direction, and first data lines 171 and first common power lines 172 that cross the first gate lines 151 in an insulated manner. Here, a pixel is defined by taking the first gate line 151, the first data line 171, and the first common power line 172 as a boundary, but is not limited thereto.

The first organic light emitting diode 71 includes a first pixel electrode 711, a first organic emissive layer 712 formed on the first pixel electrode 711, and a first common electrode 713 formed on the first organic emissive layer 712. The first pixel electrode 711 functions as a positive (+) electrode or anode being a hole injection electrode, and the first common electrode 713 functions as a negative (−) electrode or cathode being an electron injection electrode. However, an exemplary embodiment of the present invention is not necessarily limited thereto, and depending upon the ways of driving the organic light emitting diode display 100, it is possible that the first pixel electrode 711 functions as the cathode and the first common electrode 713 functions as the anode. Holes and electrons from the first pixel electrode 711 and the first common electrode 713 are injected into the organic emissive layer 712. When excitons, which are combinations of the electrons and the holes, shift from the excited state to the ground state, the light emission occurs.

Furthermore, with the organic light emitting diode display 100 according to an exemplary embodiment of the present invention, the first organic light emitting diode 71 emits light in the direction of the second substrate 210. That is, the first organic light emitting diode 71 is a front emission type. In order for the first organic light emitting diode 71 to emit light in the direction of the second substrate 210, the first pixel electrode 711 is formed as a reflective electrode, and the first common electrode 713 is formed as a transparent or semi-transparent electrode.

The first capacitor 81 has a pair of capacitor electrode plates 158 and 178, and an interlayer insulating layer 160 interposed between the two capacitor electrode plates 158 and 178. The interlayer insulating layer 160 functions as a dielectric. The capacitance is determined depending upon electric charges charged at the first capacitor 81 and the voltages applied to the two capacitor electrode plates 158 and 178.

The first switching thin film transistor 11 includes a first switching semiconductor layer 131, a first switching gate electrode 152, a first switching source electrode 173, and a first switching drain electrode 174. The first driving thin film transistor 21 includes a first driving semiconductor layer 132, a first driving gate electrode 155, a first driving source electrode 176, and a first driving drain electrode 177.

The first switching thin film transistor 11 is used as a switch for selecting the pixels to emit light. The first switching gate electrode 152 is connected to the first gate line 151. The first switching source electrode 173 is connected to the first data line 171.

The first switching drain electrode 174 is spaced apart from the first switching source electrode 173 by a distance, and is connected to any one of the capacitor electrode plates 158.

The first driving thin film transistor 21 applies a driving voltage to the first pixel electrode 711 to excite the first organic emissive layer 712 of the first organic light emitting diode 71 in the selected pixel. The first driving gate electrode 155 is connected to the capacitor electrode plate 158 connected with the first switching drain electrode 174. The first driving source electrode 176 and the other capacitor electrode plate 178 are each connected to the first common power line 172. The first driving drain electrode 177 is connected to the first pixel electrode 711 of the first organic light emitting diode 71 through a contact hole.

With the above structure, the first switching thin film transistor 11 is operated by the gate voltage applied to the first gate line 151, and transmits the data voltage applied to the first data line 171 to the first driving thin film transistor 21. The voltage with a value corresponding to a difference between the common voltage applied to the first driving thin film transistor 21 from the first common power line 172 and the data voltage transmitted from the first switching thin film transistor 11 is stored at the first capacitor 81, and the current corresponding to the voltage stored at the first capacitor 81 flows to the first organic light emitting diode 71 through the first driving thin film transistor 21 to thereby excite the first organic light emitting diode 71.

A first pixel definition layer 190 defines a first emissive area EA1 with a first opening 199. The first opening 199 exposes the first pixel electrode 711, and the first organic emissive layer 712 emits light within the first opening 199. That is, the area of the first opening 199 becomes a first emissive area EA1, and the area of the first pixel definition layer 190 becomes a first non-emissive area NA1.

Furthermore, the first organic light emitting diode 71 emits light in the direction of the second substrate 210. Accordingly, the first opening 199 and the first organic emissive layer 712 may also be formed on the first switching thin film transistor 11 and the first driving thin film transistor 21 so as to enlarge the first emissive area EA1.

The second substrate 210 is similar in structure to the first substrate 110. That is, as with the first substrate 110, the second substrate 210 includes a second switching thin film transistor 12, a second driving thin film transistor 22, a second capacitor 82 and a second organic light emitting diode 72, which are formed at each pixel. The second substrate 210 further includes second gate lines 251, arranged in a direction parallel to a direction along which the OLEDs are sequentially disposed, and second data lines 271 and second common power lines 272 that cross the second gate lines 251 in an insulated manner. Here, a pixel is defined by taking the second gate line 251, the second data line 271, and the second common power line 272 as a boundary, but is not limited thereto.

The second capacitor 82 includes a pair of capacitor electrode plates 258 and 278, and a second gate insulating layer 240 interposed between the capacitor electrode plates 258 and 278. The second gate insulating layer 240 functions as a dielectric. The capacitance is determined depending upon the electric charges charged at the second capacitor 82, and the voltages applied to the two capacitor electrode plates 258 and 278.

The second switching thin film transistor 12 includes a second switching semiconductor layer 231, a second switching gate electrode 252, a second switching source electrode 273, and a second switching drain electrode 274. The second driving thin film transistor 22 includes a second driving semiconductor layer 232, a second driving gate electrode 255, a second driving source electrode 276, and a second driving drain electrode 277.

With this structure, the second organic light emitting diode 72 emits light in the same way as in the first organic light emitting diode 71.

The second organic light emitting diode 72, however, is placed opposite to the first substrate 110, and emits light in a direction opposite to the first substrate 110. Accordingly, the second opening 299 of the second pixel definition layer 290 and the second organic emissive layer 722 are formed such that they do not overlap with the second switching thin film transistor 12 and the second driving thin film transistor 22. That is, the second organic light emitting diode 72 is formed as a rear side emission type. The second emissive area EA2 of the second organic light emitting diode 72 is smaller than the first emissive area EA1 of the first organic light emitting diode 71. In order for the second organic light emitting diode 72 to pass the light emitted from the first organic light emitting diode, the second pixel electrode 721 and the second common electrode 723 are formed with a transparent or semi-transparent electrode. However, an exemplary embodiment of the present invention is not limited thereto. The second pixel electrode 721 and the second common electrode 723 may be switched in position with each other.

The second pixel definition layer 290 defines the second emissive area EA2 with the second opening 299. The second opening 299 exposes the second pixel electrode 721, and the second organic emissive layer 722 emits light within the second opening 299. That is, the area of the second opening 299 becomes a second emissive area EA2, and the area of second pixel definition layer 290 becomes a second non-emissive area NA2.

Meanwhile, the first and second substrates 110 and 210 are arranged such that the first emissive area EA1 of the first organic light emitting diode 71 faces the second non-emissive area NA2 of the second organic light emitting diode 72, and the second emissive area EA2 of the second organic light emitting diode 72 faces the first non-emissive area NA1 of the first organic light emitting diode 71. That is, the first opening 199 of the first pixel definition layer 190 faces the second pixel definition layer 290, and the second opening 299 of the second pixel definition layer 290 faces the first pixel definition layer 190.

It is illustrated in FIG. 3 that the second switching thin film transistor 12 and the second driving thin film transistor 22 of the second substrate 210 have the same structure as that of the first switching thin film transistor 11 and the first driving thin film transistor 21 of the first substrate 110, however an exemplary embodiment of the present invention is not limited thereto. The second switching thin film transistor 12 and the second driving thin film transistor 22 may be different in structure from the first switching thin film transistor 11 and the first driving thin film transistor 21 within an available that is range well known to those skilled in the art.

The specific structure of an organic light emitting diode display 100 according to an exemplary embodiment of the present invention will now be described in detail in accordance with the sequence of deposition. The structure of a thin film transistor will be described on the basis of the first driving thin film transistor 21.

The first substrate member 111 of the first substrate 110 is formed with an insulating material such as glass, quartz, ceramic, and plastic. However, aspects of the present invention are not limited thereto. The first substrate member 111 may be formed with a metallic material such as stainless steel.

A first buffer layer 120 is formed on the first substrate member 111. The first buffer layer 120 prevents the intrusion of impurity elements while flattening the surface, and may be formed with various materials that are capable of filling such a role. For example, the first buffer layer 120 may be formed with any one of silicon nitride (SiNx), silicon oxide (SiOx), and silicon oxynitride (SiOxNy). However, the first buffer layer 120 is not necessarily required, and may be omitted depending upon the kind of the first substrate member 111 and the processing conditions.

A first driving semiconductor layer 132 is formed on the first buffer layer 120. The first driving semiconductor layer 132 may be formed with polycrystalline silicon. The first driving semiconductor layer 132 has a non-doped channel region 135, and p+ doped source and drain regions 136 and 137 formed at respective sides of the non-doped channel region 135. The dopant ion material is a P-type impurity such as boron (B), and B₂H₆ is primarily used as such a material. The impurity is differentiated depending upon the kinds of thin film transistors.

With an exemplary embodiment of the present invention, a thin film transistor with a PMOS structure using a P-type impurity is used as the first driving thin film transistor 21, but the first driving thin film transistor 21 is not limited thereto. A thin film transistor with an NMOS structure or a CMOS structure may also be used as the first driving thin film transistor 21.

A gate insulating layer 140 is formed on the first driving semiconductor layer 132 with silicon nitride (SiNx) or silicon oxide (SiOx). A first gate wire including first driving gate electrodes 155 is formed on the first gate insulating layer 140. The first gate wire further includes first gate lines 151, and other wiring lines. The first driving gate electrode 155 is overlapped with at least a part of the first driving semiconductor layer 132, and particularly with the channel region 135 thereof.

A first interlayer insulating layer 160 is formed on the first gate insulating layer 140 such that it covers the first driving gate electrodes 155. The first gate insulating layer 140 and the first interlayer insulating layer 160 commonly have through-holes exposing the source and drain regions 136 and 137 of the first driving semiconductor layer 132. The first interlayer insulating layer 160 as well as the first gate insulating layer 140 are formed with silicon nitride (SiNx) or silicon oxide (SiOx).

A first data wire including first driving source and drain electrodes 176 and 177 is formed on the first interlayer insulating layer 160. The first data wire further includes first data lines 171, first common power lines 172, and other wiring lines. The first driving source and drain electrodes 176 and 177 are connected to the source and drain regions 136 and 137 of the first driving semiconductor layer 132 via the through-holes formed at the first interlayer insulating layer 160 and the first gate insulating layer 140, respectively.

In this way, the first driving thin film transistor 21 is formed with the first driving semiconductor layer 132, the first driving gate electrode 155, and the first driving source and drain electrodes 176 and 177. The structure of the first driving thin film transistor 21 is not limited to the above, but may be altered in various manners with an available structure that is well known to those skilled in the art.

A first planarization layer 180 is formed on the first interlayer insulating layer 160 such that it covers the first data wires 172, 176, 177, and 178. The first planarization layer 180 eliminates a stepped difference and flattens the surface in order to heighten the luminous efficiency of a first organic light emitting diode 71 to be formed thereon. Furthermore, the first planarization layer 180 has a contact hole partially exposing the first drain electrode 177.

The first planarization layer 180 may be formed with at least one material selected from acrylic resin, epoxy resin, phenolic resin, polyamide resin, polyimide resin, unsaturated polyester resin, polyphenylene ether resin, polyphenylene sulfide resin, and benzocyclobutene (BCB).

Furthermore, an exemplary embodiment of the present invention is not limited to the above-described structure, and either one of the first planarization layer 180 and the first interlayer insulating layer 160 may be occasionally omitted.

A first pixel electrode 711 of the first organic light emitting diode 71 is formed on the first planarization layer 180. That is, the organic light emitting diode display 100 has a plurality of first pixel electrodes 711 disposed at a plurality of pixels, respectively. The plurality of first pixel electrodes 711 are spaced apart from each other by a distance. The first pixel electrode 711 is connected to the first drain electrode 177 through the contact hole of the first planarization layer 180.

A first pixel definition layer 190 having a plurality of first openings 199 each exposing the first pixel electrode 711 is formed on the first planarization layer 180. That is, the first openings 199 of the first pixel definition layer 190 are formed at the respective pixels one by one. The first pixel electrode 711 is disposed corresponding to the first opening 199 of the first pixel definition layer 190. However, the first pixel electrode 711 is not necessarily disposed only at the first opening 199 of the first pixel definition layer 190, but may be disposed under the first pixel definition layer 190 such that it is partially overlapped with the first pixel definition layer 190. The area of the first pixel definition layer 190 becomes substantially a first non-emissive area NA1, and the area of the first opening 199 of the first pixel definition layer 190 becomes substantially a first emissive area EA1.

The first pixel definition layer 190 may be formed with a resin such as polyacrylate resin and polyimide resin, or a silica-based inorganic material.

The first pixel definition layer 190 defines the first emissive area EA1, and furthermore, makes it easy to form a first organic emissive layer 712 while preventing electric current from concentrating on the edge of the first pixel electrode 711.

A first organic emissive layer 712 is formed on the first pixel electrode 711, and a first common electrode 713 is formed on the first organic emissive layer 712. In this way, the first organic light emitting diode 71 is formed with the first pixel electrode 711, the first organic emissive layer 712, and the first common electrode 713. The first organic emissive layer 712 is disposed between the first pixel electrode 711 and the first common electrode 713 within the first opening 199 of the first pixel definition layer 190 close thereto so as to emit light. The first common electrode 713 is formed on the first organic emissive layer 712 and the first pixel definition layer 190.

The first organic emissive layer 712 is formed with a low molecular organic material or a high molecular organic material. The first organic emissive layer 712 may have a multi-layered structure with some or all of an emission layer, a hole injection layer (HIL), a hole transport layer (HTL), an electron transport layer (ETL), and an electron injection layer (EIL). If the first organic emissive layer 712 is formed with all of the layers, the hole injection layer (HIL) is disposed on the first pixel electrode 711 being the anode, and is sequentially overlaid with the hole transport layer (HTL), the emission layer, the electron transport layer (ETL), and the electron injection layer (EIL).

Furthermore, as shown in FIG. 4, the first organic emissive layer 712 is disposed only within the first opening 199 of the first pixel definition layer 190, but an exemplary embodiment of the present invention is not limited thereto. The first organic emissive layer 712 may be formed on the first pixel electrode 711 within the first opening 199 of the first pixel definition layer 190, or may be disposed between the first pixel definition layer 190 and the first common electrode 713. Specifically, the hole injection layer (HIL), the hole transport layer (HTL), the electron transport layer (ETL), and the electron injection layer (EIL) belonging to the first organic emissive layer 712 in addition to the emission layer may be formed on the first pixel definition layer 190 as well as on the first pixel electrode 711, as with the first common electrode 713, using an open mask. By contrast, the emission layer is formed at the respective first openings 199 through a fine metal mask (FMM) process. That is, one or more layer components of the first organic emissive layer 712 may be interposed between the first pixel definition layer 190 and the first common electrode 713.

The first pixel electrode 711 and the first common electrode 713 may be formed with a transparent conductive material, or a semi-transparent or reflective conductive material, respectively. In an exemplary embodiment of the present invention, as the first organic light emitting diode 71 emits light in the direction of the second substrate 210, the first pixel electrode 711 is formed with a reflective or semi-transparent material, and the first common electrode 713 is formed with a transparent or semi-transparent material.

The transparent conductive material may be indium tin oxide (ITO), indium zinc oxide (IZO), zinc oxide (ZnO), or indium oxide (In₂O₃). The reflective material and the semi-transparent material may be selected from lithium (Li), calcium (Ca), lithium fluoride/calcium (LiF/Ca), lithium fluoride/aluminum (LiF/Al), aluminum (Al), silver (Ag), magnesium (Mg), and gold (Au).

The second substrate 210 faces the first common electrode 713 from the top side. Specifically, a second common electrode 723 is formed on the first common electrode 713. A second pixel definition layer 290 is disposed on the second common electrode 723. That is, the second pixel definition layer 290 is placed over the first opening 199 of the first pixel definition layer 190 corresponding thereto.

Furthermore, the second pixel definition layer 290 is sequentially overlaid with a second planarization layer 280, a second interlayer insulating layer 260, a second gate insulating layer 240, a second buffer layer 220, and a second substrate member 211, corresponding in position to the first opening 199 of the first pixel definition layer 190. As the overlaid layers are all formed with a transparent material, the light generated from the first organic emissive layer 712 of the first organic light emitting diode 71 sequentially passes through them, and flows to the outside.

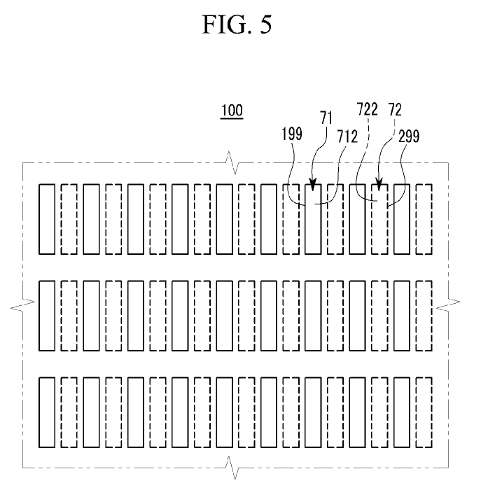

With an organic light emitting diode display 100 according to an exemplary embodiment of the present invention, as shown in FIG. 5, the first organic emissive layers 712 of the first organic light emitting diodes 71 and the second organic emissive layers 722 of the second organic light emitting diodes 72 are alternately arranged in a direction parallel to the first and second substrates 110 and 210. That is, the first and second openings 199 and 299 are arranged in an alternating manner.

In this structure, the organic light emitting diode display 100 can effectively enhance the resolution, and simultaneously prevent the occurrence of device failures.

In the organic light emitting diode display 100, the first and second organic light emitting diodes 71 and 72 separately formed on the first and second substrates 110 and 210 facing each other emit light in the same direction so as to display an image. Accordingly, it is possible with the organic light emitting diode display 100 to solve such a problem that as the resolution is heightened, the emissive area is reduced due to the non-emissive area, and the luminous efficiency is deteriorated. Consequently, a lifespan of the organic light emitting diode display 100 is prevented from being reduced.

Furthermore, as the improvement in luminous efficiency is not based on the reduction in the non-emissive area, the possible processing failures induced by a reduction of the non-emissive area can also be prevented.

A method of manufacturing an organic light emitting diode display 100 according to an exemplary embodiment of the present invention will be described with reference to FIG. 1 through FIG. 4, based on the arrangement procedures of the first and second substrates 110 and 210.

A first substrate 110 having a plurality of first organic light emitting diodes 71 each with a first emissive area EA1 and a first non-emissive area NA1, and a second substrate 210 having a plurality of second organic light emitting diodes 72 each with a second emissive area EA2 and a second non-emissive area NA2, are first formed in a separate manner. The first emissive area EA1 is defined by the first opening 199 of the first pixel definition layer 190, and the second emissive area EA2 is defined by the second opening 299 of the second pixel definition layer 290. A first organic emissive layer 712 is disposed within the first opening 199, and a second organic emissive layer 722 is disposed within the second opening 299. The first and second organic emissive layers 712 and 722 are formed by depositing an organic material using a metal mask, an ink-jet method, or a laser induced thermal imaging (LITI) method.

The specific structure of the first and second substrates 110 and 210 are as previously described. A sealant 350 is applied onto the edge of at least one of the first and second substrates 110 and 210.

Thereafter, the first and second substrates 110 and 210 are arranged such that the first emissive area EA1 of the first organic light emitting diode 71 faces the second non-emissive area NA2 of the second organic light emitting diode 72, and the second emissive area EA2 of the second organic light emitting diode 72 faces the first non-emissive area NA1 of the first organic light emitting diode 71. Specifically, the first and second substrates 110 and 210 are arranged such that the first and second organic light emitting diodes 71 and 72 are disposed as illustrated in FIG. 5.

The first and second substrates 110 and 210 are attached to each other in a vacuum-tight manner by interposing the sealant 350, which is then hardened. However, an exemplary embodiment of the present invention is not limited thereto. In addition to the vacuum sealing, the first and second substrates 110 and 210 may be attached to each other and sealed in various manners, which are well known to those skilled in the art.

With the manufacturing method, an organic light emitting diode display 100 with high resolution is fabricated effectively.

Furthermore, as the improvement in luminous efficiency is not based on the reduction in the non-emissive area, possible processing failures induced by reduction of the non-emissive area can be prevented.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An organic light emitting diode display comprising:
a first substrate having a plurality of first organic light emitting diodes each having a first emissive area and a first non-emissive area, and a first driving circuit unit for driving the first organic light emitting diodes; and
a second substrate having a plurality of second organic light emitting diodes each having a second emissive area and a second non-emissive area, and a second driving circuit unit for driving the second organic light emitting diodes,
wherein the first emissive areas of the first organic light emitting diodes face the second non-emissive areas of the second organic light emitting diodes, respectively, and the second emissive areas of the second organic light emitting diodes face the first non-emissive area of the first organic light emitting diodes, respectively.

2. The organic light emitting diode display of claim 1, wherein the first and second organic light emitting diodes emit light in the same direction.

3. The organic light emitting diode display of claim 1, wherein the first emissive areas of the first organic light emitting diodes and the second emissive areas of the second organic light emitting diodes are alternately arranged on respective opposing substrates, so as to not overlap, in a direction parallel to the first and second substrates.

4. The organic light emitting diode display of claim 1, wherein the first organic light emitting diodes each includes a first pixel electrode, a first common electrode and a first organic emissive layer disposed between the first pixel electrode and the first common electrode, and the second organic light emitting diodes each includes a second pixel electrode, a second common electrode and a second organic emissive layer disposed between the second pixel electrode and the second common electrode.

5. The organic light emitting diode display of claim 4, wherein the first and second organic emissive layers are formed by depositing an organic material using a metal mask, an ink-jet method, or a laser induced thermal imaging (LITI) method.

6. The organic light emitting diode display of claim 4, wherein the first substrate further comprises a first pixel definition layer for defining the first emissive area through a first opening, and the second substrate further comprises a second pixel definition layer for defining the second emissive area through a second opening, while the first and second organic emissive layers emit light within the first and second openings, respectively.

7. The organic light emitting diode display of claim 6, wherein the light generated from the first organic emissive layer is emitted to pass through the second pixel definition layer.

8. The organic light emitting diode display of claim 6, wherein the distance between neighboring first emissive areas and the distance between neighboring second emissive areas are at least 15 microns (μm).

9. The organic light emitting diode display of claim 8, wherein the first and second pixel definition layers are formed of an organic material.

10. The organic light emitting diode display of claim 4, wherein the first driving circuit unit further comprises a first driving thin film transistor connected to the first pixel electrodes of the first organic light emitting diodes, and the second driving circuit unit further comprises a second driving thin film transistor connected to the second pixel electrodes of the second organic light emitting diodes.

11. A method of manufacturing an organic light emitting diode display, the method comprising:
forming a first substrate having a plurality of first organic light emitting diodes each having a first emissive area and a first non-emissive area, and a first driving circuit unit for driving the first organic light emitting diodes;
forming a second substrate having a plurality of second organic light emitting diodes each having a second emissive area and a second non-emissive area, and a second driving circuit unit for driving the second organic light emitting diodes;
arranging the first and second substrates such that the first emissive areas of the first organic light emitting diodes face the second non-emissive areas of the second organic light emitting diodes, respectively, and the second emissive areas of the second organic light emitting diodes face the first non-emissive areas of the first organic light emitting diodes, respectively; and
attaching the first and second substrates to each other to seal the substrates in a vacuum-tight manner.

12. The method of claim 11, wherein the plurality of the first and second organic light emitting diodes emit light in the same direction.

13. The method of claim 11, wherein the first and second substrates are arranged such that the first emissive areas of the first organic light emitting diodes and the second emissive areas of the second organic light emitting diodes are alternately disposed on respective opposing substrates, so as to not overlap in a direction parallel to the first and second substrates.

14. The method of claim 11, wherein the first organic light emitting diodes each comprises a first pixel electrode, a first common electrode, and a first organic emissive layer disposed between the first pixel electrode and the first common electrode, and the second organic light emitting diodes each comprises a second pixel electrode, a second common electrode, and a second organic emissive layer disposed between the second pixel electrode and the second common electrode.

15. The method of claim 14, wherein the first and second organic emissive layers are formed by depositing an organic material using a metal mask.

16. The method of claim 14, wherein the first substrate further comprises a first pixel definition layer for defining the first emissive area with a first opening, and the second substrate further comprises a second pixel definition layer for defining the second emissive area with a second opening, while the first and second organic emissive layers emit light within the first and second openings, respectively.

17. The method of claim 16, wherein the light generated from the first organic emissive layer is emitted to pass through the second pixel definition layer.

18. The method of claim 16, wherein the distance between neighboring first emissive areas and the distance between neighboring second emissive areas are each at least 15 microns (μm).

19. The method of claim 18, wherein the first and second pixel definition layers are formed of an organic material.

20. The method of claim 14, wherein the first driving circuit unit further comprises a first driving thin film transistor connected to the first pixel electrodes of the first organic light emitting diodes, and the second driving circuit unit further comprises a second driving thin film transistor connected to the second pixel electrodes of the second organic light emitting diodes.

21. The organic light emitting diode display of claim 2, wherein light emitted from the first and second organic light emitting diodes is merged to display an image.

22. The organic light emitting diode display of claim 2, wherein the first organic light emitting diodes are a front emission type diode and the second organic light emitting diodes are a rear side emission type.

23. The organic light emitting diode display of claim 4, wherein the first pixel electrode is formed as a reflective electrode.

24. The organic light emitting diode display of claim 4, wherein the first common electrode, the second common electrode, and the second pixel electrode are formed as transparent or semi-transparent electrodes.

25. The organic light emitting diode display of claim 23, wherein the reflective electrodes are formed of one of lithium, calcium, lithium fluoride/calcium, lithium fluoride/aluminum, aluminum, silver, magnesium and gold.

26. The organic light emitting diode display of claim 24, wherein the transparent or semi-transparent electrodes are formed of one of indium tin oxide, indium zinc oxide, zinc oxide and indium oxide.

27. The organic light emitting diode display of claim 1, wherein the second emissive areas of the second organic light emitting diodes are smaller than the first emissive areas of the first organic light emitting diodes.

28. An organic light emitting diode (OLED) display comprising:
a plurality of substrates; and
a plurality of OLEDs disposed on one face of each of the plurality of substrates,
wherein the plurality of substrates are parallel to each other such that the faces having the OLEDs face each other, and
wherein emissive areas of the OLEDs of a bottom substrate emit light through the at least one substrate above the bottom substrate.

29. The OLED display of claim 28, wherein the plurality of OLEDs emit light in the same direction.

30. The OLED display of claim 29, further comprising:
non-emissive areas of the plurality of OLEDs,
wherein the emissive areas of the plurality of OLEDs disposed on one of the substrates emit light through the non-emissive areas of the plurality of OLEDs disposed on another one of the substrates.

31. The OLED display of claim 30 wherein the emissive areas of the one of the substrates and the emissive areas of the other of the substrates are disposed in an alternating pattern on their respective substrates so as to not overlap with each other in the direction of light emission.

32. The OLED display of claim 28, wherein each of the OLEDs includes a pixel electrode, a common electrode and an organic emissive layer disposed between the pixel electrode and the common electrode.

33. The OLED display of claim 31, wherein the organic emissive layers are formed by depositing an organic material using a metal mask, an ink-jet method, or a laser induced thermal imaging (LITI) method.

34. The OLED display of claim 31, wherein each of the substrates further comprises a pixel definition layer for defining the emissive area through an opening, while the organic emissive layers emit light through the openings.

35. The organic light emitting diode display of claim 28, wherein the distance between neighboring emissive areas is at least 15 microns (μm).

36. The organic light emitting diode display of claim 34, wherein the pixel definition layers are formed of an organic material.

37. The organic light emitting diode display of claim 29, wherein each OLED further comprises a driving circuit unit having a driving thin film transistor connected to the pixel electrode of each of the OLEDs.

38. A method of increasing a display resolution of an organic light emitting diode (OLED) display, comprising:
arranging a plurality of OLEDs disposed on a plurality of substrates in a staggered pattern on respective substrates of the plurality of substrates; and
emitting light from emissive areas of the plurality of OLEDs disposed on one of the substrates,
wherein the emitted light passes between emissive areas of the plurality of OLEDs disposed on another of the substrates.

39. The method of claim 38, wherein the plurality of OLEDs emit light in the same direction.

40. The method of claim 39, wherein the emitting of the light comprises emissive areas of OLEDs disposed on the one of the substrates emitting light through non-emissive areas of the plurality of OLEDs disposed on the other of the substrates.

41. The method of claim 40 wherein emissive areas of the one of the substrates and the emissive areas of the other of the substrates are disposed in an alternating pattern on their respective substrates so as to not overlap with each other in the direction of light emission.

42. The OLED display of claim 41, wherein each of the substrates further comprises a pixel definition layer for defining the emissive area through a opening, while the organic emissive layers emit light through the openings.

43. The organic light emitting diode display of claim 38, wherein the distance between neighboring emissive areas is at least 15 microns (μm).

44. The method of claim 38, further comprising driving the plurality of OLEDs with a driving circuit unit having a driving thin film transistor connected to a pixel electrode of each of the OLEDs.
